(19) United States
(12) Patent Application Publication
(10) Pub. No.: US 2005/0190806 A1
(43) Pub. Date: Sep. 1, 2005

(54) Semiconductor laser and manufacturing method therefor

(75) Inventors: Fumie Kunimasa, Mihara-shi (JP); Takahiro Nemoto, Mihara-shi (JP)

Correspondence Address: Barry E. Bretschneider;Morrison & Foerster LLP, Suite 300, 1650 Tysons Boulevard, McLean, VA, 22102, US

(73) Assignee: Sharp Kabushiki Kaisha, Osaka (JP)

(21) Appl. No.: 11/044,726

(22) Filed: Jan. 28, 2005

(30) Foreign Application Priority Data
Jan. 30, 2004 (JP) 2004-023137

(51) Int. Cl. H01S 5/00

(52) U.S. Cl. 372/46.01

(57) ABSTRACT

A semiconductor laser has a substrate, a laminate including at least an active layer, a ridge stripe portion on the laminate, a current blocking layer provided on lateral side surfaces of the ridge stripe portion and on an upper surface of the laminate on lateral sides of the ridge stripe portion, and a metal plating layer that covers an upper surface of the ridge stripe portion and the current blocking layer. The metal plating layer has a layer thickness that is larger on both lateral sides of the ridge stripe portion than above the ridge stripe portion by an amount approximately corresponding to a height of the ridge stripe portion so that the metal plating layer has a roughly flat upper surface.

This nonprovisional application claims priority under 35 U.S.C. §119(a) on Patent Application No. 2004-023137 filed in Japan on Jan. 30, 2004, the entire contents of which are hereby incorporated by reference.

### BACKGROUND OF THE INVENTION

The present invention relates to a semiconductor laser which has a current waveguide of, for example, a ridge stripe shape and a manufacturing method therefor.

Generally, it is desirable that semiconductor lasers have a smaller device resistance in reducing the power consumption and improving the characteristic. Particularly, in a semiconductor laser that is required to have a high output power, since the driving current is large, it is necessary to reduce the device resistance and restrain the temperature rise of the element by letting generated heat escape.

As shown in FIG. 6, a conventional semiconductor laser has a p-AlGaAsP etching stopper layer 17, a p-InGaP cladding layer 18, a p-GaAs contact layer 19, a (Ti/Pt/Au stripe pattern) metal mask 30 and an overcoat electrode 32 on an n-GaAs substrate 10 (see JP 2000-340880 A).

Then, the semiconductor laser is bonded to a heat sink (not shown) via the overcoat electrode 32 that is a metal plating layer. The assembly state is called a “junction down” in the sense that the pn junction becomes located on the heat sink side.

However, the conventional semiconductor laser has had a problem that heat generated in the active layer during the laser oscillation cannot efficiently be released to the heat sink. The reason for this is that unevenness occurs on the upper surface of the semiconductor laser (upper surface of the overcoat electrode 32) due to the ridge stripe, and this causes gaps between the semiconductor laser and the heat sink at the time of bonding the semiconductor laser to the heat sink, the gaps obstructing the release of heat generated during the laser operation to the heat sink.

### SUMMARY OF THE INVENTION

Accordingly, the object of the present invention is to provide a semiconductor laser of which the heat dissipation property is improved so as to allow efficient release of heat to be achieved even when the junction down mounting is adopted, and also to provide a manufacturing method for such a semiconductor laser.

In order to accomplish the above object, a semiconductor laser according to an aspect of the present invention comprises:
a substrate;
a laminate that is provided on the substrate and that includes at least an active layer;
a ridge stripe portion that includes a cladding layer and a contact layer successively laid on the laminate and that serves as a current path;
a current blocking layer that is provided on lateral side surfaces of the ridge stripe portion and on an upper surface of the laminate on lateral sides of the ridge stripe portion and that is formed of a dielectric; and
a metal plating layer that covers an upper surface of the ridge stripe portion and the current blocking layer,
the metal plating layer having a roughly flat upper surface.

In other words, the upper surface of the metal plating layer is roughly parallel to a surface of the substrate. And, the metal plating layer has a layer thickness that is larger on both lateral sides of the ridge stripe portion than above the ridge stripe portion by an amount approximately corresponding to a height of the ridge stripe portion.

In this case, the ridge stripe portion is formed by, for example, stacking the cladding layer and the contact layer on the laminate and thereafter partially etching the cladding layer and the contact layer. The laminate may have, for example, an etching stopper layer as the uppermost layer. The semiconductor laser may include another layer. Also, as the substrate, a semiconductor substrate made of, for example, GaAs may be used.

According to the semiconductor laser of the present invention, the upper surface of the metal plating layer is roughly flat. Therefore, it is possible to prevent the generation of a gap or void between the upper surface of the semiconductor laser and a heat sink when the upper surface of the metal plating layer is fusion bonded to the heat sink. Therefore, the area of contact between the semiconductor laser and the heat sink is increased, and the heat dissipation property is improved.

In one embodiment, the upper surface of the ridge stripe portion is formed substantially flat and the upper surface of the laminate on the lateral sides of the ridge stripe portion is also formed substantially flat.

According to the semiconductor laser, the upper surface of the metal plating layer can reliably be formed substantially flat.

In one embodiment, the semiconductor laser has a terrace portion that includes a cladding layer and a contact layer successively laid on the upper surface of the laminate beside the ridge stripe portion and that has a height approximately equal to that of the ridge stripe portion. And, the current blocking layer and the metal plating layer further cover the terrace portion.

The terrace portion(s) may be formed together with the ridge stripe portion by, for example, stacking the cladding layer and the contact layer on the laminate and thereafter partially etching the cladding layer and the contact layer.

The semiconductor laser includes the terrace portion(s) of a height approximately equal to that of the ridge stripe portion, and therefore, possible damage of the ridge stripe portion can be prevented in the semiconductor laser manufacturing process and in the mounting process.

In this case, the upper surface of the terrace portion should desirably be formed roughly flat.

In one embodiment, the semiconductor laser has a first plating feed metal layer that is arranged between the metal plating layer and the current blocking layer so as to extend along the lateral side surfaces of the ridge stripe portion and the upper surface of the laminate on the lateral sides of the ridge stripe portion; and a second plating feed metal layer that is arranged between the metal plating layer and the upper surface of the ridge stripe portion so as to extend along the upper surface of the ridge stripe portion. And, the first plating feed metal layer and the second plating feed metal layer are separated apart and not electrically connected to each other.

According to the semiconductor laser, because the first plating feed metal layer and the second plating feed metal layer are separated apart and not electrically connected together, the formation of the metal plating layer in lateral recess portions on the opposite sides of the ridge stripe portion (namely, on the upper side of the first plating feed metal layer) and the formation of the metal plating layer above the upper surface of the ridge stripe portion (namely, on the upper side of the second plating feed metal layer) can be separately carried out. Thus, a flat metal plating layer is achievable.

In one embodiment, an upper portion of the ridge stripe portion is formed in an eaves-like configuration.

In this case, the “upper portion of the ridge stripe portion” formed in eaves-like configuration may be a portion of, for example, the contact layer.

According to the embodiment, because the upper portion of the ridge stripe portion is formed in the eaves-like shape, the first plating feed metal layer and the second plating feed metal layer can easily be formed in a separated apart manner by, for example, a vacuum evaporation method so as not to be electrically connected to each other.

In one embodiment, the first plating feed metal layer is exposed at end portions of the upper surface of the laminate. That is, the metal plating layer does not exist at end portions of the semiconductor laser.

This semiconductor laser comes to have stepped portions (recess portions) at the end portions. Thus, when the semiconductor laser is bonded to the heat sink, a solder material as a bonding material is absorbed by the stepped portions (recess portions) and prevented from creeping onto the side surfaces of the semiconductor laser so that short circuit due to the solder material can be prevented.

In addition to the first and second plating feed metal layers, the semiconductor laser having the terrace portion(s) may also have a third plating feed metal layer that is arranged between the metal plating layer and the current blocking layer so as to extend along an upper surface of the terrace portion. In this case, the first plating feed metal layer, the second plating feed metal layer and the third plating feed metal layer are preferably separated apart and not electrically connected to each other.

According to the semiconductor laser, because the first plating feed metal layer, the second plating feed metal layer, and the third plating feed metal layer are separated apart and not electrically connected to each other, the formation of the metal plating layer in lateral recess portions on the opposite sides of the ridge stripe portion (namely, on the upper side of the first plating feed metal layer), the formation of the metal plating layer above the upper surface of the ridge stripe portion (namely, on the upper side of the second plating feed metal layer), and the formation of the metal plating layer above the upper surface of the terrace portion (namely, on the upper side of the third plating feed metal layer) can be separately carried out. Thus, a flat metal plating layer is achievable.

In one embodiment, an upper portion of the ridge stripe portion and an upper portion of the terrace portion are formed into an eaves-like configuration.

In this case, the “upper portion of the ridge stripe portion” and “upper portion of the terrace portion” formed in an eaves-like configuration may be a portion of, for example, the contact layer.

According to the embodiment, because the upper portion of the ridge stripe portion and of the terrace portion are formed in the eaves-like shape, the first plating feed metal layer, the second plating feed metal layer and the third plating feed metal layer can easily be formed in a separated apart manner by, for example, a vacuum evaporation method so as not to be electrically connected to each other.

In one embodiment, the third plating feed metal layer is exposed at an end portion of the upper surface of the terrace portions. That is, the metal plating layer does not exist at end portions of the semiconductor laser.

Accordingly, similarly to the foregoing embodiment, this semiconductor laser comes to have stepped portions (recess portions) at the end portions. Thus, when the semiconductor laser is bonded to the heat sink, a solder material as a bonding material is absorbed by the stepped portions (recess portions) and prevented from creeping onto the side surfaces of the semiconductor laser so that short circuit due to the solder material can be prevented.

A semiconductor laser manufacturing method according to another aspect of the present invention comprises:
forming a laminate including at least an active layer;
forming on the laminate a ridge stripe portion that includes a cladding layer and a contact layer and that becomes a current path;
forming a current blocking layer of a dielectric on lateral side surfaces of the ridge stripe portion and on an upper surface of the laminate on lateral sides of the ridge stripe portion;
forming a first plating feed metal layer on an upper side of the current blocking layer so that the first plating feed metal layer extends along the lateral side surfaces of the ridge stripe portion and the upper surface of the laminate on the lateral sides of the ridge stripe portion;
forming a second plating feed metal layer that is separated from and not electrically connected to the first plating feed metal layer, on an upper side of the ridge stripe portion so that the second plating feed metal layer extends along an upper surface of the ridge stripe portion; and
forming a metal plating layer that covers the ridge stripe portion and the laminate by applying an electric field to at least the first plating feed metal layer.

According to the semiconductor laser manufacturing method of the present invention, the metal plating layer is formed by applying an electric field to at least the first plating feed metal layer out of the first and second plating feed metal layers that are mutually separated apart and not electrically connected together, so that the upper surface of the metal plating layer can be formed roughly flat. Therefore, the generation of a gap or void between the upper surface of the semiconductor laser and the heat sink can be prevented when the upper surface of metal plating layer is bonded to the heat sink. By thus increasing the area of contact with the heat sink, a semiconductor laser with improved heat dissipation property can be manufactured.

It is acceptable to form the upper portion of the ridge stripe portion into an eaves-like configuration and concurrently form the first plating feed metal layer and the second plating feed metal layer by, for example, the vacuum evaporation method.

In one embodiment, the step of forming a metal plating layer comprises:
applying an electric field to the first plating feed metal layer to form a first metal plating layer of a height almost equal to that of the ridge stripe portion; and
applying an electric field to the first and second plating feed metal layers after having formed the first metal plating layer to form a second metal plating layer on an upper side of the first metal plating layer and of the second plating feed metal layer.

According to the manufacturing method, the metal plating layer is formed in two steps of forming the first metal plating layer and the second metal plating layer. Therefore, the upper surface of the metal plating layer can reliably be formed virtually flat by carrying out adjustment.

In one embodiment, the step of forming a metal plating layer comprises applying an electric field to the first plating feed metal layer to form a first metal plating layer of a height almost equal to that of the ridge stripe portion and thereafter, with the first metal plating layer brought into electric contact with the second plating feed metal layer, form a second metal plating layer on an upper side of the first metal plating layer and of the second plating feed metal layer.

According to the manufacturing method, the metal plating layer is formed in one step, and therefore, the upper surface of the metal plating layer can be rapidly formed roughly flat. Moreover, the electric field plating terminal requires to be provided only in one place of the first plating feed metal layer, which allows the structure to be simple.

In one embodiment, the first plating feed metal layer and the second plating feed metal layer are formed in complementary comb-like configuration in a wafer.

According to the manufacturing method, it becomes possible to form a metal plating layer on the upper side of the first plating feed metal layer in the entire wafer region by merely providing an electric field plating terminal in one place, for example, of the first plating feed metal layer. Moreover, it becomes possible to form a metal plating layer on the upper side of the second plating feed metal layer in the entire wafer region by similarly providing an electric field plating terminal in one place, for example, of the second plating feed metal layer. As is apparent, the metal plating layer can be rapidly formed.

That is, it is acceptable to form the metal plating layer by providing different electric field plating terminals on the first plating feed metal layer and the second plating feed metal layer in the process of forming the metal plating layer.

In one embodiment, the semiconductor laser manufacturing method includes forming a terrace portion that includes a cladding layer and a contact layer and has a height approximately equal to that of the ridge stripe portion, on an upper surface of the laminate beside the ridge stripe portion, and in the step of forming a current blocking layer, the terrace portion is also covered with the current blocking layer. The method further includes forming a third plating feed metal layer that is separated from the first plating feed metal layer and the second plating feed metal layer and not electrically connected thereto, on an upper side of the current blocking layer on an upper surface of the terrace portion, so that the third plating feed metal layer extends along the upper surface of the terrace portion, and in the step of forming a metal plating layer, the terrace portion is also covered with the metal plating layer.

Preferably, the terrace portion may be formed concurrently with the ridge stripe portion.

According to the manufacturing method, because the terrace portion of a height approximately equal to that of the ridge stripe portion is formed, the ridge stripe portion is prevented from being damaged in the semiconductor laser manufacturing process.

It is acceptable to concurrently form the first, second and third plating feed metal layers by the vacuum evaporation method by forming the upper portion of the terrace portion into an eaves-like configuration similarly to the upper portion of the ridge stripe portion.

In one embodiment, the step of forming a metal plating layer includes:
applying an electric field to the first plating feed metal layer to form a first metal plating layer of a height almost equal to that of the ridge stripe portion; and
applying an electric field to the first, second and third plating feed metal layers after having formed the first metal plating layer to form a second metal plating layer on an upper side of the first metal plating layer and of the second and third plating feed metal layers.

According to the manufacturing method, the metal plating layer is formed in two steps of forming the first metal plating layer and the second metal plating layer. Therefore, the upper surface of the metal plating layer can reliably be formed virtually flat by carrying out adjustment.

In one embodiment, the step of forming a metal plating layer includes applying an electric field to the first plating feed metal layer to form a first metal plating layer of a height almost equal to those of the ridge stripe portion and the terrace portion and thereafter, with the first metal plating layer brought into electric contact with the second and third plating feed metal layers, form a second metal plating layer on an upper side of the first metal plating layer and of the second and third plating feed metal layers.

According to the manufacturing method, the metal plating layer is formed in one step, and therefore, the upper surface of the metal plating layer can be rapidly formed roughly flat. Moreover, the electric field plating terminal requires to be provided only in one place of the first plating feed metal layer, which allows the structure to be simple.

Other objects, features and advantages of the present invention will be apparent from the following description.

### BRIEF DESCRIPTION OF THE DRAWINGS

The present invention will become more fully understood from the detailed description given hereinbelow and the accompanying drawings which are given by way of illustration only, and thus are not intended to limit the present invention, and wherein:

FIG. 1 is a sectional view showing a semiconductor laser according to a first embodiment of the present invention;

FIG. 2A is a sectional view showing a first process of the semiconductor laser manufacturing method of the present invention;

FIG. 2B is a sectional view showing a second process of the semiconductor laser manufacturing method of the present invention;

FIG. 2C is a sectional view showing a third process of the semiconductor laser manufacturing method of the present invention;

FIG. 2D is a sectional view showing a substitute process of the process shown in FIG. 2C;

FIG. 3 is a plan view showing the semiconductor laser without a metal plating layer;

FIG. 4 is a sectional view showing a semiconductor laser according to a second embodiment of the present invention;

FIG. 5 is a sectional view showing a state in which a semiconductor laser is attached to a heat sink; and

FIG. 6 is a sectional view showing a conventional semiconductor laser.

### DETAILED DESCRIPTION OF THE INVENTION

The present invention will be described in detail below on the basis of the embodiments thereof shown in the drawings.

### First Embodiment

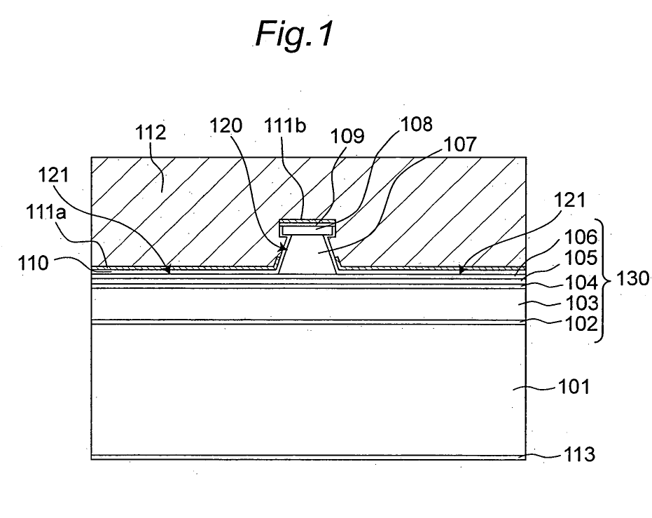

FIG. 1 shows a sectional view of a semiconductor laser of one embodiment of the present invention.

The semiconductor laser has a substrate 101, a laminate 130 provided on the substrate 101, a ridge stripe portion 120 provided on part of the laminate 130 and serving as a current path, a current blocking layer 110 provided on the opposite lateral side surfaces of the ridge stripe portion 120 and on the upper surface of the laminate 130 located on the opposite lateral sides of the ridge stripe portion 120, and a metal plating layer 112 that covers the upper surface of the ridge stripe portion 120 and the current blocking layer 110.

An n-GaAs substrate is employed as the substrate 101. An n-electrode 113 is provided on the lower surface of the semiconductor substrate 101.

The laminate 130 has an n-GaInP buffer layer 102, an n-AlGaInP cladding layer 103, a quantum well active layer 104, a p-AlGaInP first cladding layer 105 and an etching stopper layer 106 in this order from the substrate 101 side.

The ridge stripe portion 120 has a p-AlGaInP second cladding layer 107 and a p-GaAs contact layer 108 in this order from the laminate 130 side.

The upper surface of the ridge stripe portion 120 (i.e., the upper surface of the contact layer 108) is formed roughly flat. The upper surface of the laminate 130 (i.e., the upper surface of the etching stopper layer 106) on the opposite lateral sides of the ridge stripe portion 120 is formed roughly flat. Hereinafter, the upper surface of the laminate 130 on either lateral side of the ridge stripe portion 120 will be referred to as a “ridge stripe lateral flat portion 121.”

A dielectric film is employed as the current blocking layer 110. A plating metal of Au of a great thermal conductivity is employed as the metal plating layer 112. A layer thickness of the metal plating layer 112 on both lateral sides of the ridge stripe portion 120 is larger than a layer thickness of the metal plating layer 112 above the ridge stripe portion 120 by an amount approximately corresponding to a height of the ridge stripe portion 112. As a result, the upper surface of the metal plating layer 112 is formed roughly parallel to a surface of the substrate, that is, roughly flat.

Further, this semiconductor laser includes a first plating feed metal layer 111a that is arranged between the metal plating layer 112 and the current blocking layer 110 (on the laminate 130 and the ridge stripe portion 120) so as to extend along the lateral side surfaces of the ridge stripe portion 120 and the ridge stripe lateral flat portions 121, and a second plating feed metal layer 111b that is arranged between a p-side contact electrode 109, which is provided on the upper surface of the ridge stripe portion 120, and the metal plating layer 112 so as to extend along the upper surface of the ridge stripe portion 120.

The first plating feed metal layer 111a and the second plating feed metal layer 111b are separated apart and not electrically connected to each other.

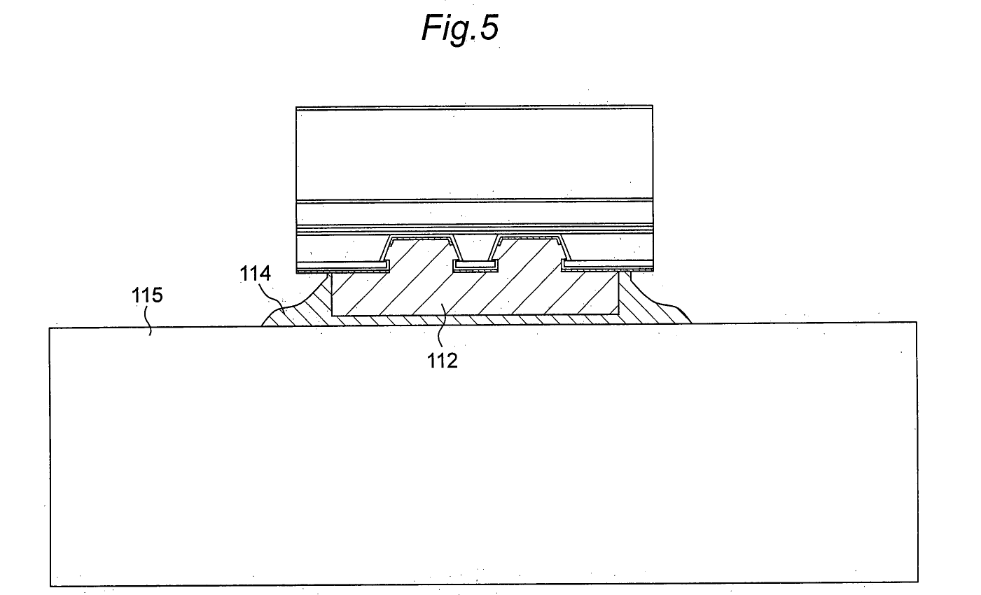

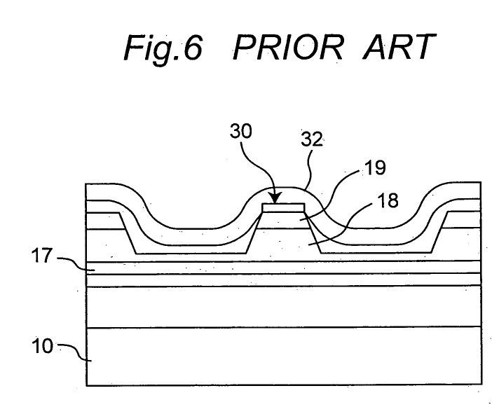

According to the semiconductor laser with the above structure, the upper surface of the metal plating layer 112 is roughly flat. Therefore, when bonding the upper surface of the metal plating layer 112 to a heat sink (for example, a heat sink 115 shown in FIG. 5), that is, when bonding the semiconductor laser to the heat sink in the junction down manner, it is possible to prevent the generation of a gap or void between the upper surface of the semiconductor laser and the heat sink. Therefore, the area of contact between the semiconductor laser and the heat sink is increased, and the heat dissipation property is improved.

In concrete, heat generated at the quantum well active layer 104 during laser operation is conducted to the heat sink through the metal plating layer 112 that has a large thermal conductivity. At this time, the metal plating layer 112, which serves as a heat conducting material, buries the side surfaces of the ridge stripe portion 120 and forms a roughly flat upper surface of the semiconductor laser. With this arrangement, a gap is prevented from being generated between the semiconductor laser and the heat sink, and the obstruction of heat conduction caused by the gap will not occur, improving the heat dissipation characteristic.

A method of manufacturing the semiconductor laser will be described next.

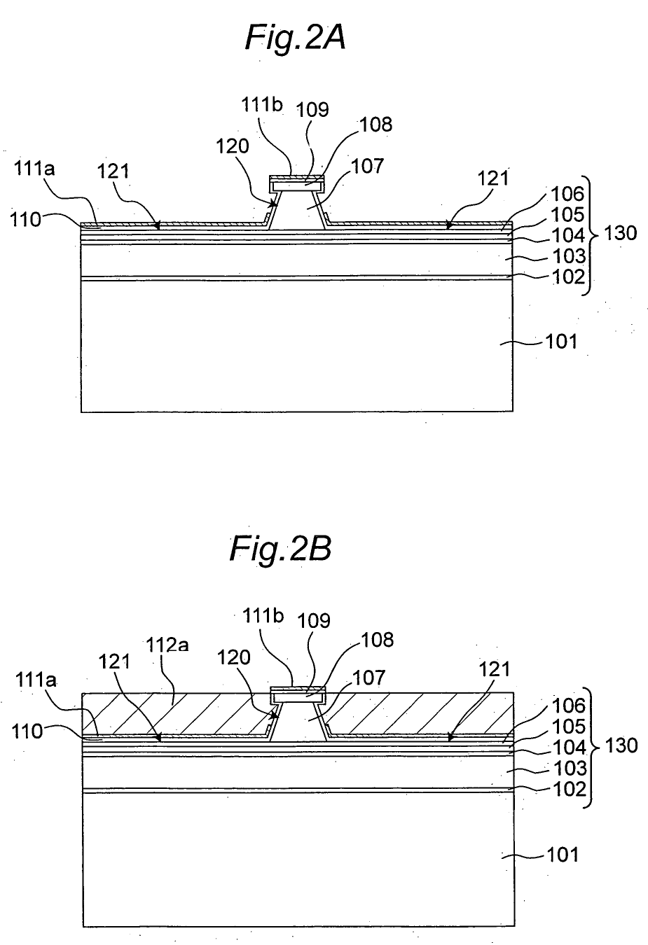

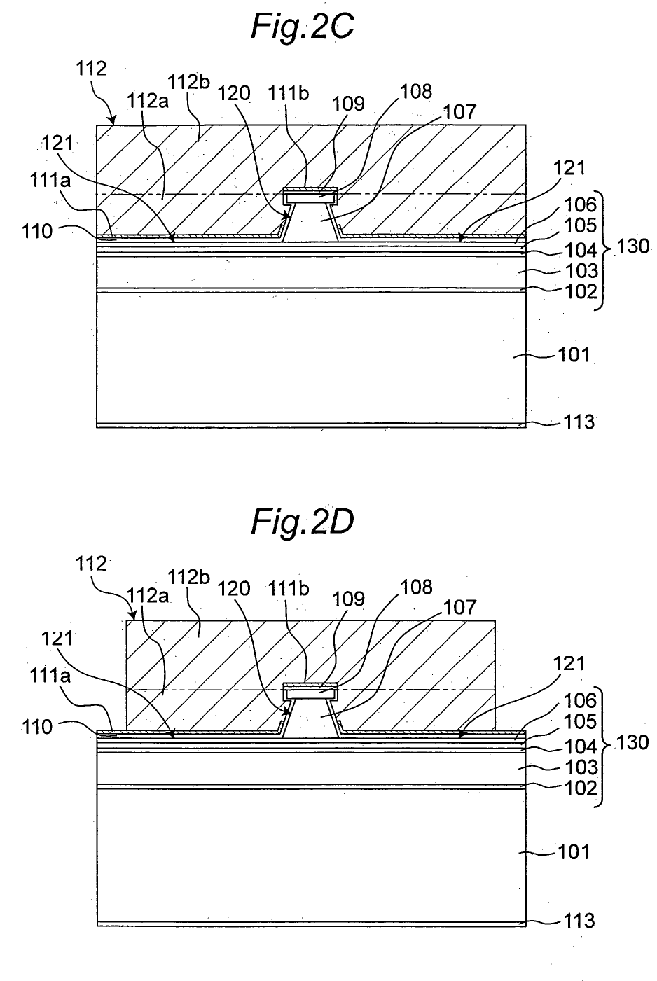

As shown in FIG. 2A, first of all, the n-GaInP buffer layer 102, the n-AlGaInP cladding layer 103, the quantum well active layer 104, the p-AlGaInP first cladding layer 105, the etching stopper layer 106, the p-AlGaInP second cladding layer 107 and the p-GaAs contact layer 108 are epitaxially grown on the substrate (wafer) 101 that is an n-GaAs substrate. The n-GaInP buffer layer 102, the n-AlGaInP cladding layer 103, the quantum well active layer 104, the p-AlGaInP first cladding layer 105 and the etching stopper layer 106 constitute the laminate 130.

Then, the p-GaAs contact layer 108 and the p-AlGaInP second cladding layer 107 are partially removed by wet etching, thereby forming on the laminate 130 the ridge stripe portion 120 that becomes an optical waveguide and a current path.

It is to be noted that the ridge stripe portion 120 may be formed by concurrently using dry etching and wet etching. At this time, the p-GaAs contact layer 108 is formed into an eaves-like shape by selective wet etching of the p-AlGaInP second cladding layer 107.

Next, the current blocking layer 110 of dielectric (such as SiO₂, SiNx, Al₂O₃, etc.) is formed on both sides of the ridge stripe portion 120, and the p-side contact electrode 109 is formed on the upper surface of the ridge stripe portion 120. It is also acceptable to omit the p-side contact electrode 109 and use the plating feed metal layers 111a and 111b formed next as a p-side contact electrode as well.

Next, the first plating feed metal layer 111a is formed on the upper side of the current blocking layer 110 so as to extend along the lateral side surfaces of the ridge stripe portion 120 and the ridge stripe lateral flat portions 121. Moreover, the second plating feed metal layer 111b, which is separated from the first plating feed metal layer 111a and is not electrically connected to the layer, is formed on the upper side of the p-side contact electrode 109 so as to extend along the upper surface of the ridge stripe portion 120. At this time, since the p-GaAs contact layer 108 has the eaves-like configuration, the first and second plating feed metal layers 111a and 111b, which are electrically separated apart, are able to be concurrently formed simply by the vacuum evaporation method.

Next, as shown in FIG. 2B, an electrolytic plating terminal (not shown) is provided only on the first plating feed metal layer 111a, and an electric field is applied to the first plating feed metal layer 111a, whereby a first metal plating layer 112a is formed to a height approximately equal to that of the ridge stripe portion 120.

Subsequently, as shown in FIG. 2C, an electrolytic plating terminal (not shown) is additionally provided on the second plating feed metal layer 111b, and an electric field is applied to the first plating feed metal layer 111a and the second plating feed metal layer 111b, whereby a second metal plating layer 112b is formed so as to have a prescribed thickness of 2.5 to 3.5 μm on the upper side of the first metal plating layer 112a and the second plating feed metal layer 111b.

As described above, it becomes possible to form the metal plating layer 112 of which the upper surface is roughly flat (in other words, roughly parallel to the substrate surface) by carrying out the metal plating process two times. Moreover, since the first metal plating layer 112a and the second plating feed metal layer 111b are electrically separated apart, the two-step metal plating process can easily be carried out.

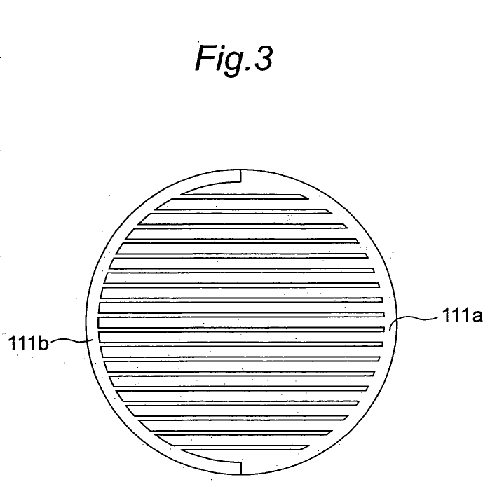

In this case, as shown in FIG. 3, the first plating feed metal layer 111a and the second plating feed metal layer 111b have comb-like shapes complementary to each other in the wafer in a plan view. It is to be noted that FIG. 3 shows a plan view of FIG. 2A in the stage prior to the formation of the metal plating layer 112.

Use of such a complementary comb-like configuration makes it possible to form the metal plating layer 112 on the upper side of the first plating feed metal layer 111a in the entire wafer region by merely providing an electric field plating terminal in one place of the first plating feed metal layer 111a. Moreover, it becomes possible to form the metal plating layer 112 on the upper side of the second plating feed metal layer 111b in the entire wafer region by similarly providing an electric field plating terminal in one place of the second plating feed metal layer 111b. Thus, the metal plating layer 112 can be rapidly formed.

Subsequently, as shown in FIG. 2C, an n-electrode 113 is formed on the lower surface of the semiconductor substrate 101 to thereby complete the semiconductor laser. Finally, the semiconductor laser is bonded to a heat sink metalized with AuSn in a junction down manner.

As described above, since the upper surface of the metal plating layer 112 of the semiconductor laser is formed roughly flat, the formation of a gap between the metal plating layer 112 and the heat sink is prevented. Since there is no gap that would obstruct the release of heat generated at the quantum well active layer 104 through the metal plating layer 112 to the heat sink during laser oscillation, the heat dissipation property is improved. With this arrangement, the thermal resistance is reduced from, for example, 40° C./W to 30° C./W, and high-power laser operation at high temperatures is achievable. Therefore, it is possible to realize a semiconductor laser which does not cause a gap or void at the time of bonding to the heat sink so that the heat radiation characteristic is improved and the temperature characteristic is also improved.

Although not shown, in the process of forming the metal plating layer 112, it is also acceptable to apply an electric field to the first plating feed metal layer 111a to form the first metal plating layer 112a of a height almost equal to that of the ridge stripe portion 120 and thereafter, with the first metal plating layer 112a brought into electric contact with the second plating feed metal layer 111b, form the second metal plating layer 112b on an upper side of the first metal plating layer 112a and of the second plating feed metal layer 111b.

As described above, since the metal plating layer 112 is formed in one step, the upper surface of the metal plating layer 112 can be rapidly formed roughly flat. Moreover, in this case, the electric field plating terminal requires to be provided only in one place of the first plating feed metal layer 111a, which allows the structure to be simple.

Moreover, as shown in FIG. 2D, the metal plating layer 112 may not exist on the upper side of the first plating feed metal layer 111a at both end positions of the upper surface of the laminate 130 by carrying out selective plating. In other words, the metal plating layer 112 is not superposed on the end portions of the laminate 130 in a plan view.

Accordingly, stepped portions (recess portions) are formed at the end portions of the semiconductor laser, and this prevents AuSn, which serves as a solder material, from creeping onto the side surfaces of the semiconductor laser by virtue of the stepped portions in bonding the semiconductor laser to the heat sink. Consequently, the short circuit of the current of the semiconductor laser is prevented, and the current characteristic of the semiconductor laser is improved.

### Second Embodiment

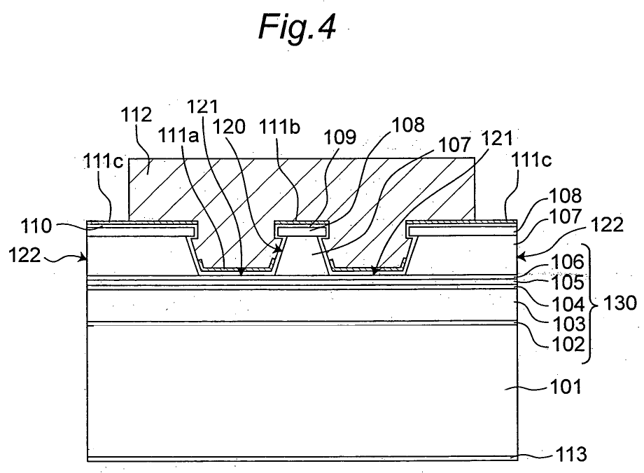

FIG. 4 shows a semiconductor laser of another embodiment of the present invention. The semiconductor laser also has terrace portions 122 on the lateral sides of the ridge stripe portion 120, which terrace portions 122 each include a cladding layer 107 and a contact layer 108 successively formed on the upper surface of the laminate 130 and which each have a height approximately equal to that of the ridge stripe portion 120. In FIG. 4, like parts as those of the first embodiment (FIG. 1) are denoted by the same reference numerals, and no description is provided therefor.

The current blocking layer 110 is laid on the terrace portions 122, and a third plating feed metal layer 111c is laid on the current blocking layer 110 so as to extend along the upper surfaces of the terrace portions 122. Then, the metal plating layer 112 is laid so as to cover the terrace portions 122. A layer thickness of the metal plating layer 112 between the ridge stripe portion 120 and each terrace portion 122 is larger than a layer thickness of the metal plating layer 112 above the ridge stripe portion 120 and the terrace portions 122 by an amount approximately corresponding to a height of the ridge stripe portion or of the terrace portions.

In concrete, in contrast to the first embodiment in which the ridge stripe portion 120 is formed by entirely etching both sides of the portion that becomes the ridge stripe portion 120, in the second embodiment embodiment, both sides of the portion that becomes the ridge stripe portion 120 are removed by only a width of 5 μm to 100 μm by etching to form the ridge stripe portion 120.

With this arrangement, the terrace portions 122, which have the height equal to that of the ridge stripe portion 120, are provided at a distance of 5 μm to 100 μm from the ridge stripe portion 120 to prevent a protruding configuration of only the ridge stripe portion 120 in the semiconductor laser manufacturing process. This arrangement makes it possible to prevent the damage of the ridge stripe portion 120 in the manufacturing process and the mounting process, thereby improving the yield of the semiconductor laser.

The first plating feed metal layer 111a, the second plating feed metal layer 111b and the third plating feed metal layer 111c are separated apart and not electrically connected together.

Referring to the formation of the metal plating layer 112, an electrolytic plating terminal is provided only on the first plating feed metal layer 111a for the formation of the metal plating layer 112. If the metal plating layer 112 is formed to a height approximately equal to that of the ridge stripe portion 120, then the formed metal plating layer 112 and the second plating feed metal layer 111b and the third plating feed metal layer 111c are brought in contact and electrically connected together. Subsequently, the metal plating layer 112 is formed entirely on the upper side of the ridge stripe portion 120, the ridge stripe lateral flat portions 121 and the terrace portions 122.

As is apparent, the metal plating process carried out in one step can achieve an effect equivalent to that of the metal plating process carried out in two steps in the first embodiment, and a metal plating layer 112 of which the upper surface is roughly flat can be formed.

Further, a portion where the metal plating layer 112 is not formed is provided in a width of 5 to 40 μm from the outer end of each terrace portion 122 by selective plating technique, the outer ends of the terrace portions 122 being the opposite ends of the semiconductor laser. That is, the third plating feed metal layers 111c located on the outer end portions of the upper surface of the terrace portions 122 are exposed. In other words, the metal plating layer 112 is not superposed on the end portions of the semiconductor substrate 101 and the laminate 130 in a plan view.

As described above, the stepped portions (recess portions) are formed at the end portions of the semiconductor laser. Thus, as shown in FIG. 5, AuSn, which serves as a solder material, is prevented from creeping onto the side surfaces of the semiconductor laser by virtue of the stepped portions (recess portions) in bonding the semiconductor laser to the heat sink 115. Consequently, the short circuit of the current of the semiconductor laser can be prevented, and the current characteristic of the semiconductor laser can be improved.

Although not shown, the process of forming the metal plating layer 112 may include a step of applying an electric field to the first plating feed metal layer 111a to form the first metal plating layer of a height almost equal to that of the ridge stripe portion 120, and a step of applying an electric field to the first, second and third plating feed metal layers 111a, 111b, and 111c after having formed the first metal plating layer to form the second metal plating layer on an upper side of the first metal plating layer and of the second and third plating feed metal layers 111b and 111c.

Because the metal plating layer 112 is formed in two steps of forming the first metal plating layer and the second metal plating layer, the upper surface of the metal plating layer 112 can reliably be formed virtually flat by carrying out adjustment.

Embodiments of the invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

1. A semiconductor laser comprising:
a substrate;
a laminate that is provided on the substrate and that includes at least an active layer;
a ridge stripe portion that includes a cladding layer and a contact layer successively laid on the laminate and that serves as a current path;
a current blocking layer that is provided on lateral side surfaces of the ridge stripe portion and on an upper surface of the laminate on lateral sides of the ridge stripe portion and that is formed of a dielectric; and
a metal plating layer that covers an upper surface of the ridge stripe portion and the current blocking layer,
the metal plating layer having a roughly flat upper surface.

2. The semiconductor laser as claimed in claim 1, wherein the upper surface of the metal plating layer is roughly parallel to a surface of the substrate.

3. The semiconductor laser as claimed in claim 1, wherein the metal plating layer has a layer thickness that is larger on both lateral sides of the ridge stripe portion than above the ridge stripe portion by an amount approximately corresponding to a height of the ridge stripe portion.

4. The semiconductor laser as claimed in claim 1, comprising:
a first plating feed metal layer that is arranged between the metal plating layer and the current blocking layer so as to extend along the lateral side surfaces of the ridge stripe portion and the upper surface of the laminate on the lateral sides of the ridge stripe portion; and
a second plating feed metal layer that is arranged between the metal plating layer and the upper surface of the ridge stripe portion so as to extend along the upper surface of the ridge stripe portion,
wherein the first plating feed metal layer and the second plating feed metal layer are separated apart and not electrically connected to each other.

5. The semiconductor laser as claimed in claim 4, wherein an upper portion of the ridge stripe portion is formed in an eaves-like configuration.

6. The semiconductor laser as claimed in claim 4, wherein the metal plating layer does not exist on an upper side of the first plating feed metal layer at end portions of the upper surface of the laminate.

7. The semiconductor laser as claimed in claim 1, comprising:
a terrace portion that includes a cladding layer and a contact layer successively laid on the upper surface of the laminate beside the ridge stripe portion and that has a height approximately equal to that of the ridge stripe portion, wherein
the current blocking layer and the metal plating layer further cover the terrace portion.

8. The semiconductor laser as claimed in claim 7, comprising:
a first plating feed metal layer that is arranged between the metal plating layer and the current blocking layer so as to extend along the lateral side surfaces of the ridge stripe portion and the upper surface of the laminate on the lateral sides of the ridge stripe portion;
a second plating feed metal layer that is arranged between the metal plating layer and the upper surface of the ridge stripe portion so as to extend along the upper surface of the ridge stripe portion; and
a third plating feed metal layer that is arranged between the metal plating layer and the current blocking layer so as to extend along an upper surface of the terrace portion,
wherein the first plating feed metal layer, the second plating feed metal layer and the third plating feed metal layer are separated apart and not electrically connected to each other.

9. The semiconductor laser as claimed in claim 8, wherein an upper portion of the ridge stripe portion and an upper portion of the terrace portion are formed into an eaves-like configuration.

10. The semiconductor laser as claimed in claim 8, wherein the metal plating layer does not exist on an upper side of the third plating feed metal layer at an end portion of the upper surface of the terrace portion.

11. The semiconductor laser as claimed in claim 7, wherein the metal plating layer has a layer thickness which is larger between the ridge stripe portion and the terrace portion than on the ridge stripe portion and the terrace portion by an amount approximately corresponding to a height of the ridge stripe portion or the terrace portion.

12. A semiconductor laser manufacturing method comprising:
forming a laminate including at least an active layer;
forming on the laminate a ridge stripe portion that includes a cladding layer and a contact layer and that becomes a current path;
forming a current blocking layer of a dielectric on lateral side surfaces of the ridge stripe portion and on an upper surface of the laminate on lateral sides of the ridge stripe portion;
forming a first plating feed metal layer on an upper side of the current blocking layer so that the first plating feed metal layer extends along the lateral side surfaces of the ridge stripe portion and the upper surface of the laminate on the lateral sides of the ridge stripe portion;
forming a second plating feed metal layer that is separated from and not electrically connected to the first plating feed metal layer, on an upper side of the ridge stripe portion so that the second plating feed metal layer extends along an upper surface of the ridge stripe portion; and
forming a metal plating layer that covers the ridge stripe portion and the laminate by applying an electric field to at least the first plating feed metal layer.

13. The semiconductor laser manufacturing method as claimed in claim 12, wherein said forming a metal plating layer comprises:
applying an electric field to the first plating feed metal layer to form a first metal plating layer of a height almost equal to that of the ridge stripe portion; and
applying an electric field to the first and second plating feed metal layers after having formed the first metal plating layer to form a second metal plating layer on an upper side of the first metal plating layer and of the second plating feed metal layer.

14. The semiconductor laser manufacturing method as claimed in claim 12, wherein said forming a metal plating layer comprises:
applying an electric field to the first plating feed metal layer to form a first metal plating layer of a height almost equal to that of the ridge stripe portion and thereafter, with the first metal plating layer brought into electric contact with the second plating feed metal layer, form a second metal plating layer on an upper side of the first metal plating layer and of the second plating feed metal layer.

15. The semiconductor laser manufacturing method as claimed in claim 12, wherein the first plating feed metal layer and the second plating feed metal layer are formed in complementary comb-like configuration in a wafer.

16. The semiconductor laser manufacturing method as claimed in claim 15, wherein said forming a metal plating layer comprises forming the metal plating layer by providing separate electric field plating terminals for the first plating feed metal layer and the second plating feed metal layer.

17. The semiconductor laser manufacturing method as claimed in claim 12, comprising:
forming a terrace portion that includes a cladding layer and a contact layer and has a height approximately equal to that of the ridge stripe portion, on an upper surface of the laminate beside the ridge stripe portion,
in said forming a current blocking layer, the terrace portion being also covered with the current blocking layer,
said method further comprising:
forming a third plating feed metal layer that is separated from the first plating feed metal layer and the second plating feed metal layer and not electrically connected thereto, on an upper side of the current blocking layer on an upper surface of the terrace portion, so that the third plating feed metal layer extends along the upper surface of the terrace portion, and
in said forming a metal plating layer, the terrace portion being also covered with the metal plating layer.

18. The semiconductor laser manufacturing method as claimed in claim 17, wherein said forming a metal plating layer comprises:
applying an electric field to the first plating feed metal layer to form a first metal plating layer of a height almost equal to that of the ridge stripe portion; and
applying an electric field to the first, second and third plating feed metal layers after having formed the first metal plating layer to form a second metal plating layer on an upper side of the first metal plating layer and of the second and third plating feed metal layers.

19. The semiconductor laser manufacturing method as claimed in claim 17, wherein said forming a metal plating layer comprises:
applying an electric field to the first plating feed metal layer to form a first metal plating layer of a height almost equal to those of the ridge stripe portion and the terrace portion and thereafter, with the first metal plating layer brought into electric contact with the second and third plating feed metal layers, form a second metal plating layer on an upper side of the first metal plating layer and of the second and third plating feed metal layers.
